(19) United States
(12) Patent Application Publication
(10) Pub. No.: US 2019/0326112 A1
(43) Pub. Date: Oct. 24, 2019

(54) DEFECT FREE SILICON GERMANIUM (SiGe) EPITAXY GROWTH IN A LOW-K SPACER CAVITY AND METHOD FOR PRODUCING THE SAME

(71) Applicant: GLOBALFOUNDRIES Inc., Grand Cayman (KY)

(72) Inventors: Shahab SIDDIQUI, Clifton Park, NY (US); Hamed PARVANEH, Clifton Park, NY (US); Mira PARK, Clifton Park, NY (US); Annie LEVESQUE, Saratoga Springs, NY (US); Yinxiao YANG, Troy, NY (US); Hongyi MI, Clifton Park, NY (US); Asli SIRMAN, Malta, NY (US)

(21) Appl. No.: 15/957,491

(22) Filed: Apr. 19, 2018

(51) Int. Cl. H01L 21/02; H01L 21/768; H01L 21/311

(52) U.S. Cl. CPC H01L 21/02057; H01L 21/31116; H01L 21/76822

(57) ABSTRACT

A method of cleaning a low-k spacer cavity by a low energy RF plasma at a specific substrate temperature for a defect free epitaxial growth of Si, SiGe, Ge, III-V and III-N and the resulting device are provided. Embodiments include providing a substrate with a low-k spacer cavity; cleaning the low-k spacer cavity with a low energy RF plasma at a substrate temperature between room temperature to 600° C.; and forming an epitaxy film or a RSD in the low-k spacer cavity subsequent to the low energy RF plasma cleaning.

### TECHNICAL FIELD

The present disclosure relates to a method, such as plasma cleaning, for removing residue from the surface of a cavity, such as a semiconductor cavity surrounded by a low-k constant spacers.

### BACKGROUND

As integrated circuits (ICs) continue to decrease in size as a consequence of market demand, the aspect ratios of topographical features, e.g., cavities, vias, and trenches, have increased. Such increase in the depth of topographical features in proportion to their width has made it difficult to remove surface contaminants from the relatively deeper and narrower topographical features.

Conventional methodology for developing and integrating low-k spacers on recessed areas of ICs is challenging, primarily due to surface contamination of low-k spacer cavities during etching. Residue on the surface of deep and narrow low-k spacer cavities creates problem during subsequent processing and operation of the ICs, as by impeding desired electrical connection between the low-k spacer cavity and a subsequently deposited layer and reducing the adhesion between the low-k spacer cavity and a subsequently deposited layer. Further, it is difficult to epitaxially grow a defect free silicon germanium (SiGe) in a low-k spacer cavity with surface contaminants.

A need therefore exists for methodology for removing surface contaminants from a low-k spacer cavity to enable defect free epitaxial growth of SiGe or silicon (Si).

### SUMMARY

An aspect of the present disclosure is a method of cleaning a low-k spacer cavity with a low energy radio frequency (RF) plasma at a specific substrate temperature.

Another aspect of the present disclosure is a device with a defect free SiGe in a low-k spacer cavity.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing a substrate with a low-k spacer cavity; cleaning the low-k spacer cavity with a low energy RF plasma at a substrate temperature between room temperature to 600° C.; and forming an epitaxy film or a raised source/drain (RSD) in the low-k spacer cavity subsequent to the low energy RF plasma cleaning.

Aspects of the present disclosure include cleaning a low-k spacer cavity by: placing a substrate with the low-k spacer cavity within a reaction chamber; and exposing the low-k spacer cavity to a low energy RF plasma of hydrogen/argon (H₂/Ar), hydrogen (H₂), argon (Ar), helium (He), or a combination thereof. Further aspects include cleaning the low-k spacer cavity with the low energy RF plasma at a substrate temperature between room temperature to 600° C. Another aspect includes generating the low energy RF plasma by delivering a power level of 400 watts to 1000 watts to the reaction chamber. Additional aspects include introducing a low energy H₂/Ar RF plasma into the reaction chamber to establish a pressure of 15 millitorr (mTorr) to 20 mTorr. Further aspects include cleaning the low-k spacer cavity with the low energy Ar/H₂ RF plasma at a flow of Ar between 700 standard cubic centimeters per minute (sccm) to 950 sccm and H₂ between 10 sccm to 100 sccm. Another aspect includes cleaning the low-k spacer cavity with the low energy H₂/Ar RF plasma for a period of 15 seconds to 240 seconds. Additional aspects include forming the epitaxy film on a substrate that includes a fin-type field effect transistor (FinFET) and forming the RSD, wherein the substrate includes a planar partially depleted silicon on insulator (PDSOI) or a fully depleted silicon on insulator (FDSOI).

Another aspect of the present disclosure is a method including: providing a FinFET with a low-k spacer cavity over a substrate; cleaning the low-k spacer cavity with a low energy H₂/Ar RF plasma at a substrate temperature between room temperature to 600° C.; and forming an epitaxy film in the low-k spacer cavity subsequent to performing the low energy H₂/Ar RF plasma cleaning.

Aspects of the method include cleaning the low-k spacer cavity by: placing the FinFET with the low-k spacer cavity within a reaction chamber; and exposing the low-k spacer cavity to the low energy H₂/Ar RF plasma. Another aspect includes cleaning the low-k spacer cavity with the low energy H₂/Ar RF plasma at the substrate temperature between room temperature to 600° C. Other aspects include the low energy H₂/Ar RF plasma generated by delivering a power level of 400 watts to 1000 watts to the reaction chamber. A further aspect includes cleaning the low-k spacer cavity with the low energy H₂/Ar RF plasma at a flow of Ar between 700 sccm to 950 sccm and H₂ between 10 sccm to 100 sccm, wherein the low-k spacer cavity is cleaned with the low energy H2/Ar RF plasma for a period of 15 seconds to 240 seconds. Additional aspects include the low energy H₂/Ar RF plasma introduced into a reaction chamber to establish a pressure of 15 mTorr to 20 mTorr.

Aspects of the present disclosure include providing a low-k spacer cavity over a PDSOI or a FDSOI substrate; cleaning the low-k spacer cavity with a low energy H₂/Ar RF plasma at a substrate temperature between room temperature to 600° C.; and forming a RSD in the low-k spacer cavity subsequent to performing the low energy H₂/Ar RF plasma cleaning.

Another aspect includes cleaning the low-k spacer cavity by: placing the low-k spacer cavity over the PDSOI or the FDSOI within a reaction chamber; and exposing the low-k spacer cavity to the low energy H₂/Ar RF plasma. Other aspects include cleaning the low-k spacer cavity with the low energy H₂/Ar RF plasma at the substrate temperature between room temperature to 600° C. A further aspect includes the low energy H₂/Ar RF plasma generated by delivering a power level of 400 watts to 1000 watts to the reaction chamber. Additional aspects include cleaning the low-k spacer cavity with the low energy H₂/Ar RF plasma at a flow of Ar between 700 sccm to 950 sccm and H₂ between 10 sccm to 100 sccm, wherein the low-k spacer cavity is cleaned with the low energy H2/Ar RF plasma for a period of 15 seconds to 240 seconds.

Another aspect of the present disclosure is a device including an epitaxy film or a RSD in a low-k spacer cavity by the method of claims 1, 9 and 15.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1 through 3 illustrate cross-sectional views of a process flow for cleaning a low-k spacer cavity in a substrate of a FinFET, in accordance with an exemplary embodiment; and

FIGS. 4 through 6 illustrate cross-sectional views of a process flow for cleaning the exposed surface of a PDSOI or a FDSOI substrate prior to source/drain epitaxial growth, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of surface contaminants on a low-k constant spacer attendant upon a cavity etch. The problem is solved, inter alia, by cleaning the surface of the low-k spacer cavity by a low energy RF plasma at a specific substrate temperature.

Methodology in accordance with embodiments of the present disclosure includes providing a substrate with a low-k spacer cavity. The low-k spacer cavity is cleaned with a low energy RF plasma at a substrate temperature between room temperature to 600° C.; and an epitaxy film or a RSD is formed in the low-k spacer cavity subsequent to the low energy RF plasma cleaning.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

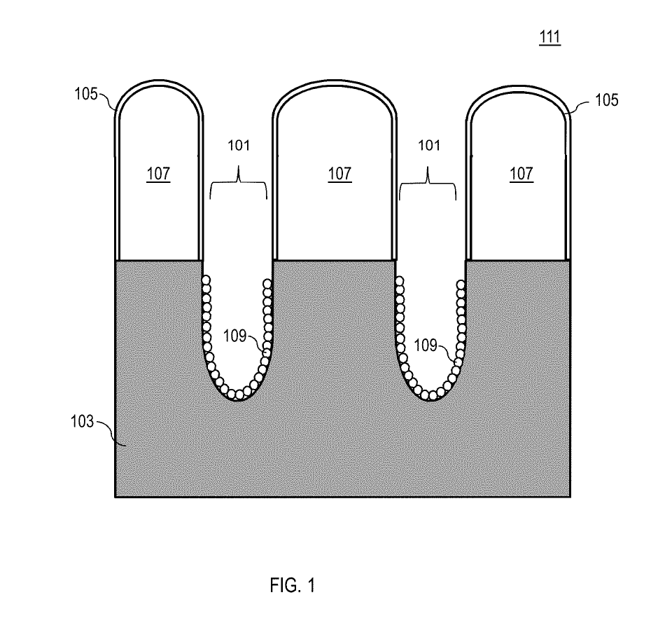

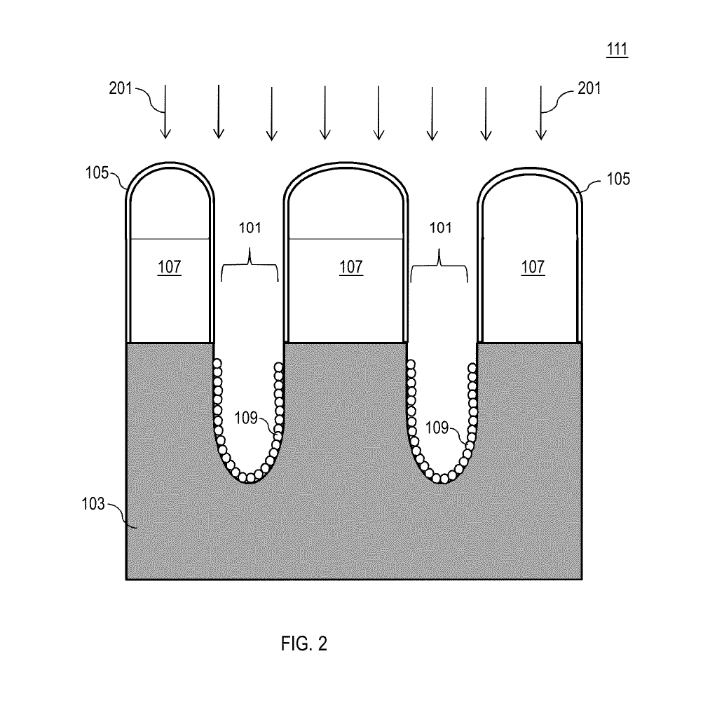

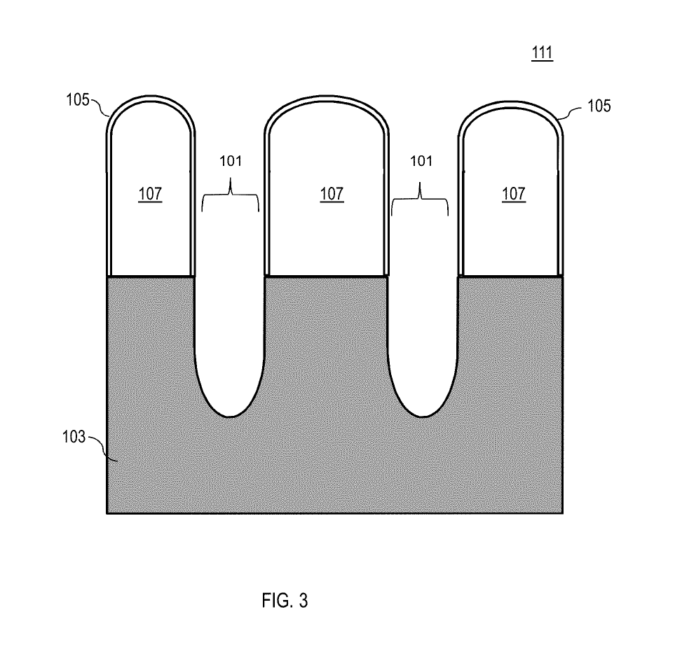

FIGS. 1 through 3 illustrate cross-sectional views of a process flow for cleaning a low-k spacer cavity in a substrate of a FinFET, in accordance with an exemplary embodiment. Referring to FIG. 1, a low-k spacer cavity 101 is formed, e.g., having a depth of 10 nm to 100 nm and a width of 10 nm to 40 nm, as by etching, in a Si substrate 103 between low-k spacers 105 formed over gates 107. A layer of residual materials 109 is typically formed, e.g., of carbon (C), fluorine (F), fluorocarbons (CFₓ) or like materials, on the surface of the low-k spacer cavity 101 during the cavity etch. These residual materials tend to cause problem during operation of ICs if they are allowed to remain, e.g., preventing a desired electrical connection between the substrate 103 and a subsequently deposited layer. As illustrated in FIG. 2, residual materials 109 are removed by cleaning the low-k spacer cavity 101 with a low energy RF plasma (represented by arrows 201) of H₂/Ar, H₂, Ar and/or He, at a substrate temperature between room temperature to 600° C. For example, the FinFET 111 is placed within a reaction chamber (not shown for illustrative convenience) and the low-k spacer cavity 101 is exposed to the low energy RF plasma generated by delivering a power level of 400 watts to 1000 watts. A flow of Ar/H₂ RF plasma is introduced in to the reaction chamber, e.g., at a flow rate of 700 sccm to 950 sccm for Ar and 10 sccm to 100 sccm for H₂, and the Ar/H₂ RF plasma maintained at a pressure of 15 mTorr to 20 mTorr in the reaction chamber. The Ar/H₂ RF plasma effectively cleans the residual materials 109 in between 15 seconds to 240 seconds at the substrate temperature between room temperature to 600° C., as depicted in FIG. 3. In one instance, the low energy Ar/H₂ RF plasma includes between 1% to 100% by volume of H₂ and between 1% to 100% by volume of Ar. Subsequent to the low energy RF plasma cleaning, an epitaxy film, e.g., SiGe, Si or like materials, (not shown for illustrative convenience) is formed in the low-k spacer cavity 101.

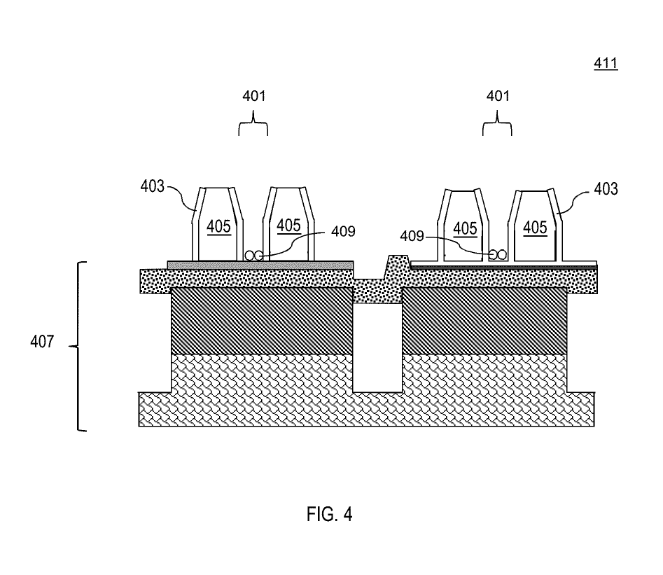

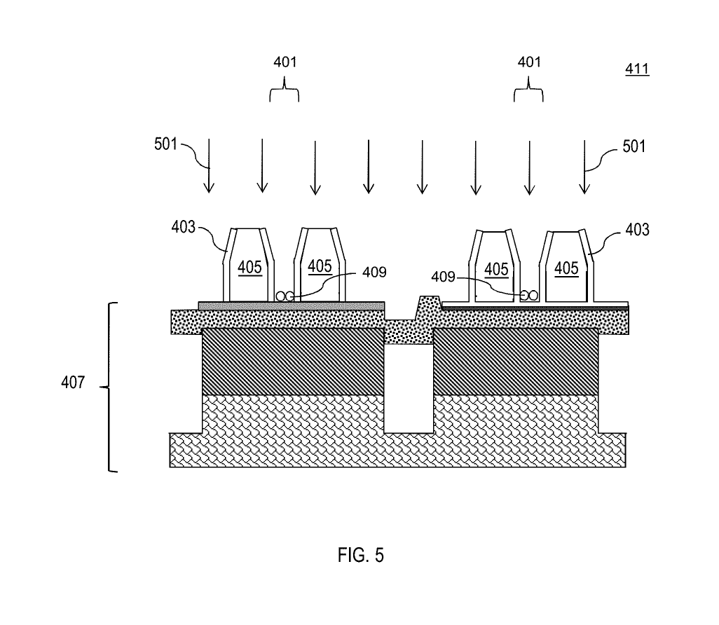

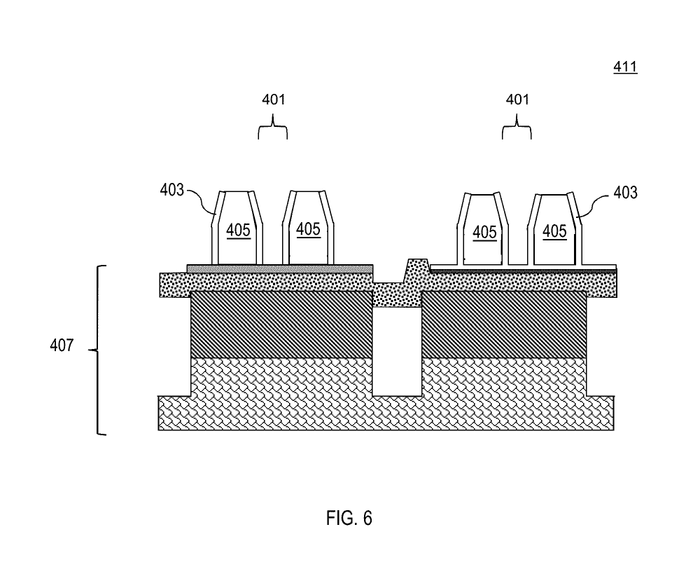

FIGS. 4 through 6 illustrate cross-sectional views of a process flow for cleaning the exposed surface of a PDSOI or a FDSOI substrate prior to source/drain epitaxial growth, in accordance with an exemplary embodiment. Referring to FIG. 4, a low-k spacer cavity 401 is formed pursuant to etching the low-k spacer 403, the etching may expose the substrate between low-k spacers 403 formed on the sidewalls of the gates 405 over a PDSOI or a FDSOI substrate 407. A layer of residual materials 409 is typically formed, e.g., of C, F, CFₓ or the like materials, on the surface of the low-k spacer cavity 401 during the etching. Then, as illustrated in FIG. 5, residual materials 409 are removed by cleaning the low-k spacer cavity 401 with a low energy RF plasma of H₂/Ar, H₂, Ar and/or He (represented by arrows 501) at a substrate temperature between room temperature to 600° C. For example, the PDSOI or the FDSOI device 411 is placed within a reaction chamber (not shown for illustrative convenience). Then, the low-k spacer cavity 401 is exposed to the low energy RF plasma generated by delivering a power level of 400 watts to 1000 watts to the reaction chamber. A flow of Ar/H₂ RF plasma is introduced in to the reaction chamber, e.g., at a flow rate of 700 sccm to 950 sccm for Ar and 10 sccm to 100 sccm for H₂, and the Ar/H₂ RF plasma maintained at a pressure of 15 mTorr to 20 mTorr in the reaction chamber. The Ar/H₂ RF plasma effectively cleans the residual materials 409 in 15 seconds to 240 seconds at the substrate temperature between room temperature to 600° C., as depicted in FIG. 6. Subsequent to the Ar/H₂ RF plasma cleaning, a RSD (not shown for illustrative convenience) is formed in the low-k spacer cavity 401.

The embodiments of the present disclosure can achieve several technical effects, such as removal of surface contaminants inside a low-k spacer cavity without causing dielectric erosion and/or reducing a breakdown voltage, a defect free epitaxial growth of SiGe or Si inside a low-k spacer cavity, and a reduction in missing epitaxy or other defects resulting from nucleation issue during the epitaxial growth process. In addition, the present disclosure enables desired electrical connection and adhesion between the low-k spacer cavity and a subsequently deposited layer. Further, a clean and residue free interface results in a better Gate to sub contact (PC-TS) leakage due to controlled dopant distribution. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure enjoys industrial applicability in any of various types of FinFETs, PDSOI or FDSOI devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a substrate with a low-k spacer cavity;
cleaning the low-k spacer cavity with a low energy radio frequency (RF) plasma at a substrate temperature between room temperature to 600° C.; and
forming an epitaxy film or a raised source/drain (RSD) in the low-k spacer cavity subsequent to the low energy RF plasma cleaning.

2. The method according to claim 1, comprising cleaning the low-k spacer cavity by:
placing the substrate with the low-k spacer cavity within a reaction chamber; and
exposing the low-k spacer cavity to the low energy RF plasma of hydrogen/argon (H₂/Ar), hydrogen (H₂), argon (Ar), helium (He), or a combination thereof.

3. The method according to claim 2, comprising cleaning the low-k spacer cavity with the low energy RF plasma at the substrate temperature between room temperature to 600° C.

4. The method according to claim 2, wherein the low energy RF plasma is generated by delivering a power level of 400 watts to 1000 watts to the reaction chamber.

5. The method according to claim 2, wherein a low energy H₂/Ar RF plasma is introduced into the reaction chamber to establish a pressure of 15 millitorr (mTorr) to 20 mTorr.

6. The method according to claim 5, comprising cleaning the low-k spacer cavity with the low energy H₂/Ar RF plasma at a flow of Ar between 700 standard cubic centimeters per minute (sccm) to 950 sccm and H₂ between 10 sccm to 100 sccm.

7. The method according to claim 5, comprising cleaning the low-k spacer cavity with the low energy H₂/Ar RF plasma for a period of 15 seconds to 240 seconds.

8. The method according to claim 1, comprising forming the epitaxy film on the substrate that comprises a fin-type field effect transistor (FinFET) and forming the RSD, wherein the substrate comprises a planar partially depleted silicon on insulator (PDSOI) or a fully depleted silicon on insulator (FDSOI).

9. A method comprising:
providing a fin-type field effect transistor (FinFET) with a low-k spacer cavity over a substrate;
cleaning the low-k spacer cavity with a low energy hydrogen/argon (H₂/Ar) radio frequency (RF) plasma at a substrate temperature between room temperature to 600° C.; and
forming an epitaxy film in the low-k spacer cavity subsequent to performing the low energy H₂/Ar RF plasma cleaning.

10. The method according to claim 9, comprising cleaning the low-k spacer cavity by:
placing the FinFET with the low-k spacer cavity within a reaction chamber; and
exposing the low-k spacer cavity to the low energy H₂/Ar RF plasma.

11. The method according to claim 10, comprising cleaning the low-k spacer cavity with the low energy H₂/Ar RF plasma at the substrate temperature between room temperature to 600° C.

12. The method according to claim 10, wherein the low energy H₂/Ar RF plasma is generated by delivering a power level of 400 watts to 1000 watts to the reaction chamber.

13. The method according to claim 9, comprising cleaning the low-k spacer cavity with the low energy Ar/H₂ RF plasma at a flow of Ar between 700 standard cubic centimeters per minute (sccm) to 950 sccm and H₂ between 10 sccm to 100 sccm, and wherein the low-k spacer cavity is cleaned with the low energy H2/Ar RF plasma for a period of 15 seconds to 240 seconds.

14. The method according to claim 9, wherein the low energy H₂/Ar RF plasma is introduced into a reaction chamber to establish a pressure of 15 millitorr (mTorr) to 20 mTorr.

15. A method comprising:
providing a low-k spacer cavity over a partially depleted silicon on insulator (PDSOI) or a fully depleted silicon on insulator (FDSOI) substrate;
cleaning the low-k spacer cavity with a low energy hydrogen/argon (H₂/Ar) radio frequency (RF) plasma at a substrate temperature between room temperature to 600° C.; and
forming a raised source/drain (RSD) in the low-k spacer cavity subsequent to performing the low energy H₂/Ar RF plasma cleaning.

16. The method according to claim 15, comprising cleaning the low-k spacer cavity by:
placing the low-k spacer cavity over the PDSOI or the FDSOI within a reaction chamber; and
exposing the low-k spacer cavity to the low energy H₂/Ar RF plasma.

17. The method according to claim 16, comprising cleaning the low-k spacer cavity with the low energy H₂/Ar RF plasma at the substrate temperature between room temperature to 600° C.

18. The method according to claim 16, wherein the low energy H₂/Ar RF plasma is generated by delivering a power level of 400 watts to 1000 watts to the reaction chamber.

19. The method according to claim 15, comprising cleaning the low-k spacer cavity with the low energy H₂/Ar RF plasma at a flow of Ar between 700 standard cubic centimeters per minute (sccm) to 950 sccm and H₂ between 10 sccm to 100 sccm, and wherein the low-k spacer cavity is cleaned with the low energy H2/Ar RF plasma for a period of 15 seconds to 240 seconds.

20. A device comprising:
an epitaxy film or a raised source/drain (RSD) in a low-k spacer cavity by the method of claims 1, 9 and 15.
